(19) United States
(12) Patent Application Publication
(10) Pub. No.: US 2025/0155291 A1
(43) Pub. Date: May 15, 2025

(54) METHOD FOR EMISSIVITY-CORRECTED PYROMETRY

(71) Applicant: AIXTRON SE, Herzogenrath (DE)

(72) Inventor: Dirk HEYDHAUSEN, Aachen (DE)

(21) Appl. No.: 18/833,084

(22) PCT Filed: Jan. 25, 2023
(86) PCT No.: PCT/EP2023/051819

§ 371 Date: Aug. 13, 2024

(30) Foreign Application Priority Data
Jan. 26, 2022 (DE) 10 2022 101 806.7

(51) Int. Cl. G01J 5/00; C23C 16/52

(52) U.S. Cl. CPC G01J 5/0003; C23C 16/52

(57) ABSTRACT

A method for coating a substrate, in which emissivity values (U_{E,n}) and reflectance values (U_{R,n}) are determined using pyrometers in order to control the temperature of the substrate. Since the wavelengths of the two pyrometers differ slightly, the raw temperature determined from the emissivity value (U_{E,n}) cannot be optimally compensated for using the reflectance value (U_{R,n}). The angular frequencies (ω_{E}, ω_{R}) of the curves of the two values (U_{E,n}) and (U_{R,n}) oscillating over time t differ slightly from one another, leading to an oscillation of the actual temperature value. To counteract this phenomenon, values modified by a numerical time transformation are used rather than the measured values.

### RELATED APPLICATIONS

This application is a National Stage under 35 USC 371 of and claims priority to International Application No. PCT/EP2023/051819, filed 25 Jan. 2023, which claims the priority benefit of DE Application No. 10 2022 101 806.7, filed 26 Jan. 2022.

### FIELD OF THE INVENTION

The invention relates to a method for coating a substrate with at least one layer, wherein measurement value pairs {U_{E,n}, U_{R,n}} are determined multiple times in succession with at least one optical measuring device on the layer during the deposition, each of which contains an emissivity value U_{E,n} that corresponds to the thermal radiation output measured at a first wavelength, and a reflectance value U_{R,n}, which is measured at a second wavelength and differs only slightly at most from the first wavelength, wherein temperature values Tᵢ of a substrate temperature are calculated from the measurement value pairs {U_{E,n}, U_{R,n}}, wherein the emissivity values U_{E,n} and the reflectance values U_{R,n} each lie on a curve that oscillates with an angular frequency ω_{E}, ω_{R} over time t, and a quotient of the angular frequencies ω_{E}, ω_{R} differs slightly from 1. The temperature values Tᵢ are preferably used as actual values T_{act}, with which the substrate temperature is regulated using a temperature control device to regulate to temperature of the substrate with respect to a setpoint Tₛₑₜ.

The invention further relates to an apparatus having a computing device that is programmable and programmed in such a way that correction values are calculated.

### BACKGROUND

U.S. Pat. No. 6,398,406 B1 forms the technical background of the invention. The method of emissivity-corrected pyrometry described there, also referred to as reflectivity- or reflectance-corrected or emissivity-compensated, enables non-contact optical temperature measurement during thin-film deposition with unknown and continuously changing optical properties of the measurement object. The pyrometry method for non-contact temperature measurement makes use of the equation between the thermal radiation emitted by the hot measurement object and the temperature of the object, which is described by the known Planck's radiation equation and in practice is captured by a corresponding previous calibration unambiguously except for the emissivity of the object. The measurement object can be any optically accessible surface in the process chamber that is relevant for monitoring or controlling the temperature. For this invention, the measurement object is in particular the surface of the substrate or substrates in the process chamber during the deposition process in which a semiconductor layered structure is produced with different, almost stoichiometric compounds from group III (Al, Ga, In) and nitrogen.

JP 2017-017251 A describes a method in which the temperature values of a substrate temperature are determined from measurement value pairs that each contain an emissivity value and a reflectance value. The two sinusoidal measurement curves are slightly phase-shifted. With the aid of a numerical time transformation, in which minimum values and maximum values of the curve are determined at different times, a transformed curve is formed and is used for the calculation of the temperature values instead of the emissivity values or reflectance values.

The state of the art is also represented by the following publication: W. G. Breiland, Technical Report SAND2003-1868 June 2003, hereinafter referred to as Breiland 2003.

The state of the art also includes DE 10 2018 106 481 A1, which describes a species-related apparatus.

DE 44 19 476 C2 describes a method with which the emitted and reflected radiation from the substrate can be measured during the deposition of a layer.

DE 10 2020 111 293 A1 describes emissivity-corrected pyrometry for minimizing residual oscillation.

The known method of emissivity correction is based on determining the missing, unknown emissivity by measuring the reflectance of the surface of the measurement object. The emissivity is determined with the help of Kirchhoff's law for the case of opaque substrates as ε=1−ρ. The detection wavelength of the pyrometer is selected in such a way that the selected substrate (in this case silicon) is opaque for the wavelength at the typical operating temperatures (T=600-1200° C.), i.e. at a value in the range from 800 nm to 1000 nm. The reflectance is measured at exactly the same wavelength as the thermal emission so that the method works with sufficient accuracy. The light required for this can be provided by a laser. But the light required for this can also be generated by a diode. Given a finite width of the filter, this may even be more suitable than using a laser. In practice, pyrometers do not have a sharp measuring wavelength but rather a wavelength interval (about +10 nm, but also narrower or wider). A thermal radiation output is therefore measured at a first wavelength. A reflectance value is measured at a second wavelength. Ideally, the two light wavelengths are identical, but for technical reasons they are slightly different, wherein the deviation may in particular be not more than 1%, 2%, 5% or at the most 10% from the light wavelength. It may also be greater in some cases. The light source should preferably have a spectrum that conforms to Planck's distribution formula. This interval width and the centroid wavelength of the emission and reflectance measurements must match as closely as possible. The reflectance is measured by emitting light of the defined wavelength at the location of the sensor, reflecting it at the wafer surface when incident vertically and reflecting it at the same location as the pyrometer measurement to the extent possible. The reflectance is determined from the measured signal intensity of the reflected light with the aid of a previous calibration. In practice, the thermal emission of the object and the reflectance can often not be measured simultaneously, but rather alternately, so that the reflectance measurement does not interfere with the measurement of the thermal emission. See also the “lock-in technology” described in DE 44 19 476 C2 on this subject.

Two different calibration steps are required to accurately measure the temperature; performing the calibrations allows the determination of calibration parameters, which are included in the calculation of the temperature from the measurement signals. This involves the calibration of the emission measurement using a blackbody radiation source (blackbody oven, special reference sources) which establishes the link between the intensity signal and the measurement temperature. During the measurement, the use of the calibration parameters determined in this way allows the “raw temperature” to be determined, which has not yet been corrected for the effect of the unknown emissivity. An independent calibration step is used to determine a calibration parameter, so that each measured reflectance signal is assigned a reflectance value from the interval 0 . . . 1. This calibration step is carried out on substrates of well-known reflectance (or emissivity in the case of opaque substrates), such as silicon immediately after the desorption process step (native oxide removal) at a known temperature and on an uncontaminated surface and before the start of layer deposition.

When depositing a thin layer with a constant growth rate, if the described known method of emissivity correction is not used, a sinusoidally oscillating temperature measurement is observed, which is related to the interference effects in the transparent thin layer (Fabry-Perot oscillations). In the specific case of MOCVD deposition of GaN or AlGaN on silicon or another material at temperatures in the range from 950 to 1100° C., the oscillations are up to ±30° C. The aim of the procedure is to reduce the temperature oscillations to below ±2° C., better still ±1° C. This problem can occur not only in the material system described previously, but also in other material systems, for example other III-V compound semiconductors or II-IV compound semiconductors.

If the temperature measurement method described in the prior art is carried out as described, a number of errors occur, which are described below. All of these sources of error lead to the emissivity correction being carried out incompletely or artificially high. The erroneous emissivity correction manifests itself in remaining temperature oscillations (residual oscillations) whose amplitude is greater than the desired degree of error. The document JP 2017-017251 A cited in the introduction already presents one approach intended to minimize this source of error.

It has been found that the material system GaN (AlGaN) on silicon is particularly susceptible to the error sources described, because due to the values of the refractive indices for the layer and wafer material and because of the meeting of the transparent layer and opaque substrate, the measured reflectance values R oscillate between values close to zero and 0.5. Other material systems may also be affected by this problem, e.g., the AlGaInP/GaAs system. It should be noted that in this case the effect is not as significant.

The sources of error observed can be the following errors, which also occur in practice:
Unknown exact value of the reflectance of the calibration object during reflectance calibration, so the value of the reflectance used in the calibration does not match the physical reflectance, and the reflectance values used for the emissivity correction are incorrect;
Errors in the adjustment and setup of the measuring optics;
Scattering at layer boundaries in the semiconductor layer structure when measuring the reflectance, so that part of the actually reflected light is not recorded;
Scattered radiation from hot surfaces of the process chamber, which reaches the measuring head through multiple reflections on the process chamber walls and on the wafer surface.

In the production of electronic components in which the material pairings described previously or others are used, such as transistors for circuits for power conversion or high-frequency amplification, the control and repeatability of the deposition process and the yield of usable components per wafer are severely impaired in the embodiment of the known method on which the invention is based, because the measured wafer temperature is used for temperature control in a closed control loop. The temperature control regulates a heating device in such a way that the measured temperature constantly corresponds to a specific setpoint; the physical temperature then oscillates accordingly around the remaining amplitude of the not fully corrected temperature oscillations, which represent a measurement artifact. The component has a multi-layer structure deposited on a substrate, which has a first section and a second section. Transition layers, in particular AlGaN, and buffer layers, in particular made of GaN, are deposited in the first section. An AlGaN barrier layer is deposited on the GaN buffer layer in such a way that a two-dimensional electron gas forms in the region of the layer boundary between the GaN layer and the AlGaN barrier layer. The impairment in reproducibility is related in particular to the fact that the component structure is typically composed of a sequence of functional blocks consisting of a thin AlN seed layer on the Si substrate, a transition layer sequence, a thick GaN buffer layer sequence and a relatively thin but temperature-sensitive barrier layer of AlGaN or AlInN. At the end of the buffer layer, depending on the random phase position of the remaining measurement temperature oscillation, the deviation of the physical temperature from the target value from run to run or from wafer to wafer will have different values, which are translated into different values of the composition of the barrier layer, which is critical for the function of the component.

The following theoretical correction of this measurement method to compensate for the sources of error described above is given in the state of the art and is based on a mathematically deducible fact that the effect of a series of error sources can be effectively compensated for by an additional correction value γ, so that the remaining oscillations can be theoretically reduced to zero.

A similar method is described in DE 10 2020 126 597 A1.

The starting point for the invention is the equation between the measurement signal detected in the pyrometer due to the thermal emission of the wafer surface and the temperature of the wafer surface, wherein account is taken of the emissivity of the wafer surface, which differs from 1 due to the varying physical and optical properties during layer growth.

This equation is described by Planck's radiation law in Wien's approximation and is presented as follows here:

$${U}_{E} = ε \cdot A \cdot {e}^{\frac{B}{T}} \qquad ( 1 )$$

$$where ε = 1 - α \cdot {U}_{R} \qquad ( 1 a )$$

The symbols represent the following variables:
U_{E}: Measurement signal of thermal emission from the wafer surface,
U_{R}: Measurement signal of reflectance from the wafer surface,
ε: Emissivity,
A, B: Calibration parameters, where B<0,
α: Calibration parameter for normalization of reflectance, establishes the equation between the measurement signal U_{R} and the physical reflectance R, with 0≤R≤1.

The measurement signals for the thermal emission U_{E} and for the reflectance of the wafer surface U_{R} are recorded as closely together in time and space as possible. The signal that corresponds to the thermal emission is the radiation intensity, which is captured with a detector in the pyrometer and converted into a temperature measurement value by the calibration parameters A and B that were determined possibly with the help of a blackbody calibration conducted before start-up. The reflectance signal is produced by measuring the intensity of a light signal having a wavelength as close as possible to the thermal emission measurement, which is emitted by the measuring unit and reflected back to the detector from the reflective wafer surface. Due to optical thin-film effects (Fabry-Perot effect), the reflectance of the wafer surface exhibits an approximately sinusoidal variation over time during deposition of the thin films. With the typical growth rates from 0.5 to 5 μm/h in GaN-on-Si processes and the wavelength of 950 nm used for the measurement, the duration of the oscillation periods is up to 10 minutes.

From equations (1) and (1a), the following equation

$${U}_{E} = A \cdot {e}^{\frac{B}{T}} \cdot ( 1 - α \cdot {U}_{R} ) \qquad ( 2 )$$

can be used to calculate the actual temperature for each measurement of the measurement value pair as follows:

$${T}_{i} = \frac{B}{ln ( {U}_{E , i} ) - ln ( A \cdot ( 1 - α \cdot {U}_{R , i} ) )} \qquad ( 3 )$$

In the specific configuration of the method for a planetary reactor with multiple single wafers, the pyrometer is attached immovably to the top of the process chamber on an optical window with visual connection to a position on the surface of the substrate carrier. For reasons of thermal averaging, the substrates are rotated slowly around the center of the reactor during the coating. A typical rotation period takes about 12 seconds, which is equivalent to five revolutions per minute. However, the rotation rate may be faster or slower. Accordingly, a measurement signal pair U_{E} and U_{R} is recorded at a certain location on the wafer that is of interest for the measurement every 12 seconds. FIGS. 1 and 2 show the configuration used. The measurement site 13 may also be a measurement zone, over which several measurements are taken. The measurement signal pair U_{E} and U_{R} corresponds to the averaged values over this zone. The site 13 or the measurement zone may be on each wafer 7, and may be located in the middle of the wafer, on the edge of the wafer, or anywhere in between.

It is only possible to carry out a rough correction of the emissivity value using the method described above. In fact, it is not technically possible to determine the reflectance signal and the emission measurement signal at exactly the same wavelength. The wavelengths differ from one another by a few nanometers or fractions of a nanometer for example because of dexterity accuracies or tolerances of the filters. In particular, the wavelength of the emissivity values curve is temperature-dependent. The period length of the oscillating curves, of the emissivity value on the one hand and the reflectance values on the other, is about 300 seconds. The difference between the period lengths is in the order of about 0.1 second. It may be up to a maximum of 0.1 second, 0.2 seconds, 0.5 seconds, or even a maximum of 1 second. Because of this path difference, the temperature determined using equation 3 oscillates with a residual oscillation, as is illustrated schematically in FIG. 3. However, the document JP 2017-017251 A cited above has already suggested a way in which this residual oscillation might be reduced or eliminated. However, in order to do this, it is necessary to measure one complete oscillation of a curve.

### SUMMARY OF THE INVENTION

The problem addressed by the invention is that of improving the method described previously with regard to the accuracy of the determination of the correction value.

The problem is solved with the invention stated in the claims, wherein the subordinate claims represent not only advantageous further developments of the invention as presented in the main claim, but also represent standalone solutions to the problem.

Firstly, and essentially, it is suggested that the emissivity values and reflectance values are not used as such to calculate the actual value of the substrate surface temperature, but rather transformed values U*ᵢ are formed either from the emissivity values U_{E,i} or the reflectance values U_{R,i}. These transformed values are then used instead of the emissivity values or reflectance values in the calculation of the actual values. The transformation may be a modification of the emissivity value or reflectance value. With the transformation, the curve of the emissivity values or reflectance values can be mapped to a curve that oscillates with a different angular frequency over time. The transformation may be carried out in such manner that after the transformation, two curves, either a transformed emission curve and the reflectance curve or a transformed reflectance curve and the emission curve, whose angular frequency is identical, are available. The curve of the measurement values that is to be transformed is thus somewhat stretched or compressed temporally, so it is possible to speak of a temporal transformation of the measurement values. In detail, the measurement values as such are transformed. In order to determine the transformed value U*ᵢ, measurement values may be used that are measured at different times successively, for example measurement values that are measured one immediately after the other.

According to a first aspect of the invention, the measurement values used to calculate the transformed values contain the current measurement value, that is to say the most recently measured value in each case. For preference, this value and the one measured immediately before it are used.

But besides the current measurement value, a measurement value measured immediately before the previous one may also be used. In fact, several measurement values measured before the current measurement value may be used.

Alternatively or in combination with the first aspect of the invention, it may be provided that one value in each case of a gradient of a curve of the measured emissivity values or reflectance values is calculated from at least two measurement values. This gradient value is used in the calculation of a transformed value.

With the further development of the state of the art according to the invention, it is thus possible to calculate an updated transformed value at any time.

It may be provided that a transformation factor is used for the transformation. The transformation factor may be determined in preliminary tests. The transformation factor may be the quotient of the angular frequencies of the curves of the reflectance values and/or emissivity values oscillating over time. It may be provided that the transformation factor is >1, but essentially only slightly larger than 1. On the other hand, depending on the formulation of the transformation, the transformation factor may also be smaller than 1, but essentially only slightly smaller than 1. The value of the quotient may be for example in the ranges 1-10⁻² and 1-10⁻⁶ or 1+10⁻⁶ and 1+10⁻². According to a preferred variant of the invention, temporally transformed emissivity values or reflectance values are used instead of the emissivity values or reflectance values to calculate the actual temperature. It is further preferred that for the time transformation, a transformed time is formed that consists of the untransformed time and the transformation factor a, and optionally a phase factor b as follows

$${t}_{i}^{*} = a \cdot {t}_{i} + b \qquad ( 4 )$$

The measurement values are then converted into transformed values as follows:

$${U}_{i} ( t ) \to {U}_{i}^{*} ( {t}_{i}^{*} ) \qquad ( 5 )$$

The transformation is preferably made with the following equation

$${U}_{i}^{*} = {U}_{i} - ( 1 - \frac{1}{a} ) \cdot {t}_{i} \cdot {U}_{i}^{′} , \qquad ( 5 a )$$

where U′ᵢ is the temporal derivative of the gradient of the curve of either the emissivity values or the reflectance values plotted over time, which can be calculated preferably using a differential quotient. For example, if the measurement values for reflectance U_{R,i} are transformed, the actual temperature is calculated according to the following equation

$${T}_{i} = \frac{B}{ln ( {U}_{E , i} ) - ln ( A \cdot ( 1 - α \cdot {U}_{R , , i}^{*} ) )} . \qquad ( 11 )$$

By selecting the transformation factor a as quotient of the angular frequencies of both curves plotted over time

$$a = \frac{{ω}_{E}}{{ω}_{R}} \qquad ( 6 )$$

the leading curve of the measurement value, for example the reflectance measurement value, is stretched in such a way that the period length of the curve of the transformed values is the same as the period length of the trailing curve. The transformation preferably forms a temporally transformed gradient triangle. In the process, the gradient of the untransformed curve and the transformed time are determined at the time the measurement value is recorded. The transformed measurement value is obtained by multiplying the gradient of the untransformed curve with the reciprocal transformation factor and the transformed time. Preferably, the transformation always transforms the leading curve in such a way that the period length of the transformed curve matches the period length of the trailing curve.

With the method according to the invention, a transformation factor a, possibly determined in preliminary tests, may be used to calculate an actual temperature with incrementally smaller residual oscillations, in each case using the current measurement values and at least one of the measurement values recorded in the past.

One or more preliminary test(s) is/are conducted to determine the transformation factor. In these preliminary tests, a layer is deposited on a substrate with the same or similar process parameters to those with which the method with the features described above is performed. The measurement value pairs yielded thereby, each of one emissivity value and one reflectance value, are stored. Then, an optimization is carried out, in which an experimental value of a transformation factor a is varied using the stored measurement values and the abovementioned equations until the residual oscillation of the plotted temperature over time curve is minimal, that is to say for example the area integral below the residual oscillation curve reaches a minimum.

But the transformation factor can also be determined during the same “run”, for example if other layers, in particular buffer layers, are deposited before the deposition of the layer.

It is further possible to adapt the transformation factor continuously. Continuous adaptation may be carried out particularly if multiple layers are deposited one on top of the other on a substrate.

The transformation preferably makes use of a temporal derivative of the measurement curve plotted over time, which is formed by differential quotients.

$${U}_{i}^{′} = \frac{{U}_{i} - {U}_{i - n}}{{t}_{i} - {t}_{i - n}} . \qquad ( 7 )$$

The gradient of the transformed measurement curve can be calculated from the gradient of the untransformed measurement curve with the aid of the transformation factor. The differential quotient can be calculated from measurement values that are measured in immediate succession. The differential quotient is preferably calculated with successive measurement points. However, these do not have to be the last two. Other measurement points can be used, particularly if the time point to be measured from the transformed interval expires. However, measurement values that were not measured in immediate succession but originate from more widely separated measurements can also be used to calculate the differential quotient. This is applied particularly when the transformed measurement value lies outside an interval between the two measurement values used to determine the differential quotient. Then, the measurement interval can be stretched temporally backwards until the transformed measurement value falls within the measurement interval whose measurement values are used to determine the differential quotient.

The temperature values that were calculated with the method described previously represent the surface temperatures of the substrates. The temperature of the substrates is preferably regulated with a temperature control device, wherein the control circuit used for this is given a value, against which an actual value is controlled. Preferably, the calculated temperature value that was calculated using the transformation according to the method described above is used as the actual value.

The invention also relates to an apparatus for carrying out a method, wherein the apparatus is equipped with two optical measurement devices, with which the emissivity value and the reflectance value can be measured. This is preferably a single measurement device that functionally incorporates two optical measurement devices, which alternately measures the emissivity value or the reflectance value. The apparatus is equipped with a computing device for calculating the actual value of a temperature of a surface of a substrate or of the layer deposited on the substrate. The computing device is configured to form transformed values from either the emissivity values or the reflectance values using a transformation in the manner described previously, and to use these instead of the emissivity values or reflectance values to calculate the actual values.

The invention further relates to a CVD reactor with a temperature control device for controlling the temperature of a substrate, for example a heating device and an apparatus for determining the actual value of the substrate temperature, as was described previously. The CVD reactor may have a gas inlet element, with which process gases can be fed in a process chamber. The process gases, which may be organometallic compounds from main group III and hydrides from main group V, may be fed into the process chamber together with an inert gas, e.g., a noble gas or hydrogen. However, process gases containing compounds from main groups II and VI or compounds from main group IV may also be used. One or more substrates are positioned on a susceptor, which forms the floor of the process chamber. The temperature control of the substrate is assured by heating the susceptor. For this purpose, a heating device is provided that may preferably be arranged below the susceptor. The heating device is controlled by the computing device, with reference to an actual value, which is calculated from reflectance values and emissivity values in the manner described earlier.

The previously described method may also be modified to such effect that the time transformation is carried out optionally for the reflectance values or the emissivity values, wherein the prefix of the transformation factor may be either positive or negative. Either a linear interpolation or a non-linear interpolation may be used for the time transformation. The linear interpolation has the advantage that only two measurement points are required in order to determine a value lying between them. Higher level interpolations need more measurement points. The method relates particularly to a temperature determination using a transformation. But the invention relates particularly and advantageously to the calculation of a temperature that is to be used as actual value in a closed control loop.

### BRIEF DESCRIPTION OF THE DRAWINGS

In the following text, an exemplary embodiment of the invention will be explained with reference to accompanying drawings. In the drawings:

FIG. 1 is a schematic illustration of a device for carrying out the method;

FIG. 2 is a schematic illustration of the detail along line II-II in FIG. 1 onto a susceptor 4 on which substrates 7 are arranged, and measurement points 13, with which emissivity values U_{E,i} and reflectance values U_{R,i} may be measured by means of a reflectance measuring device 11 and an emissivity measuring device 12;

FIG. 3 is a schematic illustration of the temporal progression of a measurement curve U_{R} recorded over time of a multiplicity of reflectance measurement values and of a measurement curve U_{E} recorded over time of a multiplicity of emissivity measurement values, wherein the curves have been normalized for the sake of clarity. The angular frequency ω_{E} of the measurement curve of the emissivity values is slightly greater than the angular frequency ω_{R} of the measurement curve of the reflectance values. The consequence of this is an oscillation of the sum of the two normalized curves, which is shown as a solid line and characterizes the progression of the calculated temperature;

FIG. 4 shows the detail IV of FIG. 3, wherein a somewhat larger quotient of the two angular frequencies has been used for purposes of clarity, and the dotted line does not represent the sum of the two curves but rather a transformed curve of the reflectance values; and

FIG. 5 shows the detail V of FIG. 4.

### DETAILED DESCRIPTION

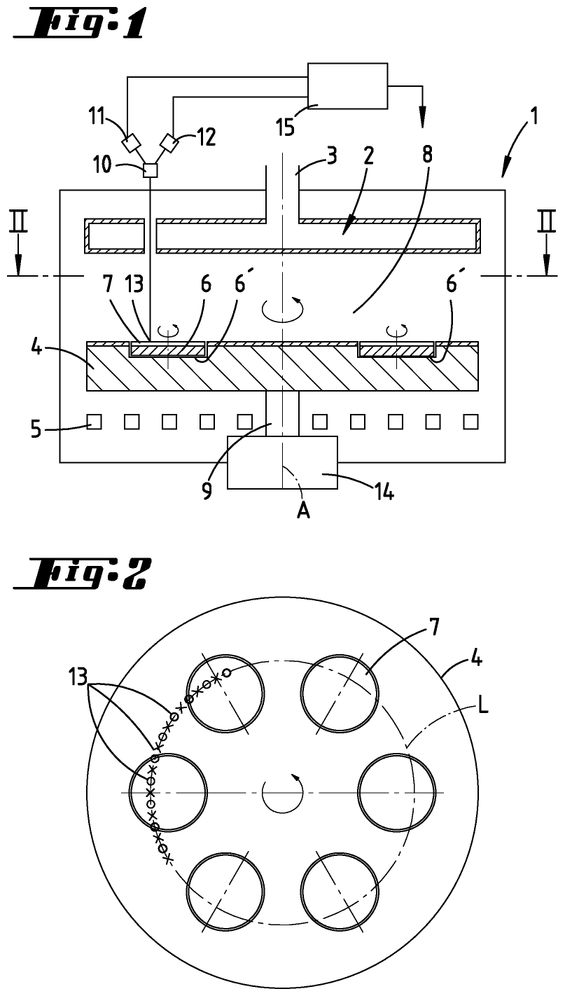

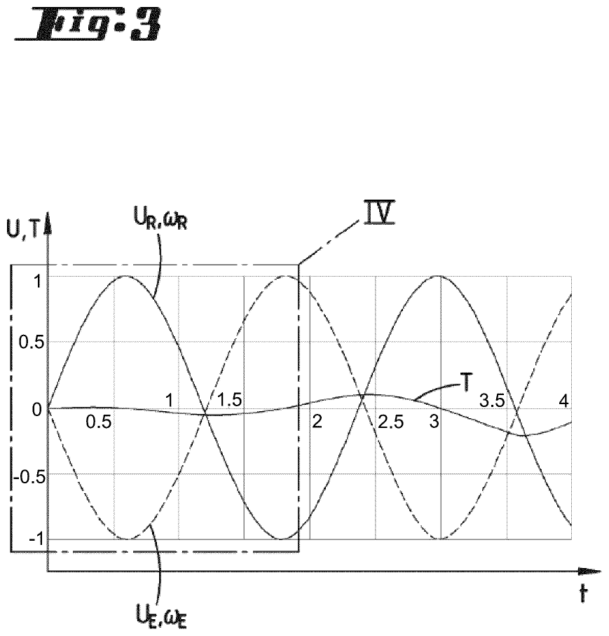

The CVD reactor shown in FIGS. 1 and 2 has a reactor housing 1, a heating device 5 arranged therein, a susceptor 4 arranged above the heating device 5, and a gas inlet element 2 for introducing, for example, TMGa, TMAI, NH₃, AsH₃, PH₃ and H₂. The susceptor 4 is driven in rotation about a vertical axis of rotation A with the aid of a rotary drive device 14. For this purpose, a drive shaft 9 is connected on the one hand to the rotary drive device 14 and on the other hand to the underside of the susceptor 4.

Substrates 7 lie on the horizontal surface of the susceptor 4 facing away from the heating device 5. Substrate holders 6 are provided, on which the substrates 7 lie. The substrates 7 are located radially outside the axis of rotation A and are held in position by substrate holders.

Two measuring devices may be provided. An emissivity measuring device 12 can be formed by a pyrometer. A reflectance measuring device 11 may also be formed by a pyrometer. A beam splitter 10 may be provided, with which an input beam can be divided between the two measuring devices 12, 11. The beam path is incident on the substrate 7 at a measuring point 13. FIG. 2 suggests that the measuring point 13 migrates over all of the substrates 7 during a rotation of the susceptor 4.

However, the two measurement devices 11, 12 may also be combined in a single measurement device.

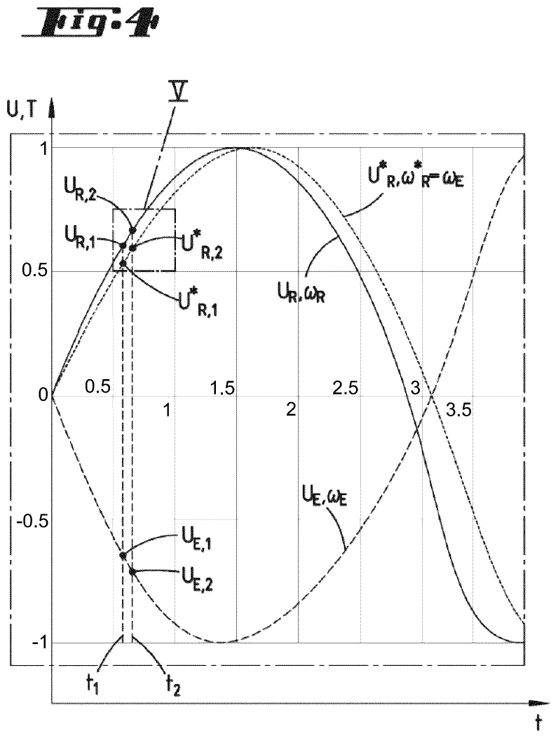

FIG. 3 shows in the solid line an interpolated measurement curve through a multiplicity of measurement points, not illustrated individually, of the reflectance measurement values U_{R,i} measured with a measurement device 11. The oscillation is attributable to reflections on the boundary surface layers. The dashed line corresponds to a curve interpolated through a multiplicity of measurement values of the emissivity U_{E,i} measured with the measurement device 12. Here too, the oscillation is attributable to reflections on the boundary surfaces of the layer. The two curves have a path difference, as a result of tolerances in the filters used, for example, with the result that their angular frequencies OR and ω_{E} are slightly different from one another. As a consequence of this deviation, the sum of the two curves oscillates. This is represented by the solid line labelled by T, which is qualitatively equivalent to the course of a calculated temperature.

The temperature T can be calculated with the aid of the equations 1 to 2 stated above after the equation 3 stated above.

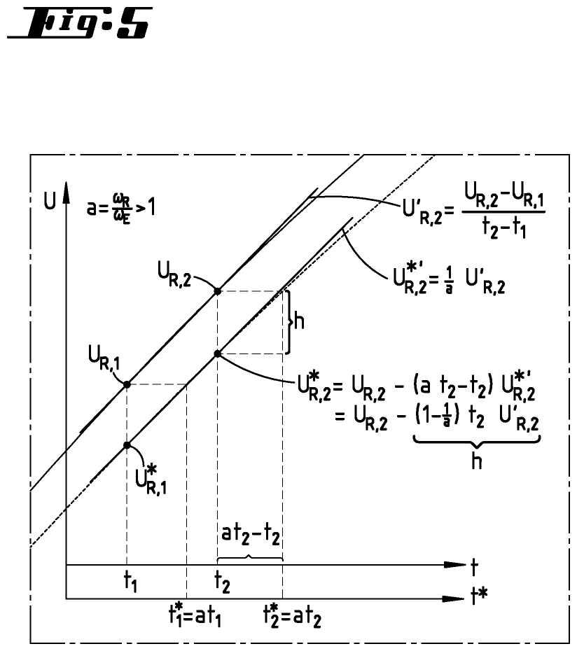

FIG. 4 shows that due to the larger angular frequency ω_{R} of the measurement curve of reflectance values U_{R,i} plotted over time t, this curve leads the measurement curve of emissivity values U_{E}, ε. According to the invention, a transformed curve is formed from the reflectance measurement values U_{R,i} by means of a suitable transformation, and is represented by the dotted line. For the calculation of the temperature, transformed measurement values U_{R,i} are used, which lie on the transformed curve at measurement times tᵢ. In FIG. 4, measurement value pairs {U_{E,i}, U_{R,i}} and one transformed measurement value U*_{R,i} calculated therefrom are represented, for index i equal to 1 and 2. The angular frequency ω*_{R} of the transformed curve U*_{R} has the same value, or almost the same value, as the angular frequency ω_{E} of the curve of the emissivity values U_{E,i}.

FIG. 5 serves to explain the method for determining the transformed measurement values U*_{R,i} in detail. In reality, the curves represented in FIGS. 3 and 4 are not exact sinusoidal curves. They are only suggested as sinusoidal curves in FIGS. 3, 4 and 5 for the purpose of explanation. Nevertheless, the curves have a periodicity, so that in preliminary tests, the angular frequencies ω_{R} and ω_{E} can be determined by depositing a layer. From these two angular frequencies, the following quotient is formed

$$a = \frac{{ω}_{E}}{{ω}_{R}} \qquad ( 6 )$$

Value α is used as the transformation factor for the transformation. The transformation is a temporal transformation, wherein a transformed time t*ᵢ

$${t}_{i}^{*} = a \cdot {t}_{i} \qquad ( 4 a )$$

is formed. With this time transformation, the solid curve U_{R}, which reflects the temporal course of the measurement values for reflectance U_{R,i}, is stretched in such a way that its period length reflects that of the dashed curve U_{E}, which reflects the temporal course of the measurement values for emissivity U_{E}, ε. The time-transformed curve U*_{R} is dotted. In order to calculate the temperature T, the transformed measurement values U*_{R,i} are used and correspond to the values the transformed curve has at the non-transformed times tᵢ.

The calculation of a transformed measurement value U*_{R,i} is carried out based on the example illustrated in FIG. 5 with the two reflectance measurement values U_{R,1} and U_{R,2} taken at times t₁ and t₂ in the manner of a Taylor series that is discontinued after the first term. An amount is subtracted from the reflectance measurement value U_{R,2}, which amount results from the gradient U*′_{R,2} of the transformed reflectance curve and the difference from transformed time and untransformed time at₂-t₂.

$${U}_{R , 2}^{*} = {U}_{R , 2} - ( a \cdot {t}_{2} - {t}_{2} ) \cdot {U}_{R , 2}^{* ′} \qquad ( 8 )$$

The gradient U_{R,2} can be obtained from the gradient of the untransformed curve of reflectance measurement value U_{R,2} with the aid of transformation factor a

$${U}_{R , 2}^{* ′} = \frac{1}{a} {U}_{R , 2}^{′} \qquad ( 9 )$$

so that the transformed measurement value U*′_{R,2} can be calculated directly from the measurement value U_{R,2} and its temporal derivative U*_{R,2} as follows:

$${U}_{R , 2}^{*} = {U}_{R , 2} - ( 1 - \frac{1}{a} ) \cdot {t}_{2} \cdot {U}_{R , 2}^{′} \qquad ( 10 )$$

The temporal derivative U′_{R,2} is then calculated with a differential quotient using at least one previously recorded measurement value U_{R,1}.

$${U}_{R , 2}^{′} = \frac{{U}_{R , 2} - {U}_{R , 1}}{{t}_{2} - {t}_{1}} \qquad ( 7 a )$$

The value calculated with equation 10 can then be used directly to calculate the actual value Tᵢ

$${T}_{i} = \frac{B}{ln ( {U}_{E , \dot{ι}} ) - ln ( A \cdot ( 1 - α \cdot {U}_{R , i}^{*} ) )} , \qquad ( 11 )$$

wherein i in the exemplary embodiment is given the value 2, and the transformed measurement value U*_{R,2} is calculated using two measurement values that have been taken at different times tᵢ.

In the exemplary embodiment (see FIG. 5), the transformed measurement value U*_{R,2} is situated at the bottom between two measurement values U_{R,1} and U_{R,2} that have been recorded one immediately after the other at times t₁ and t₂, respectively. Under other conditions, where the transformed measurement value U*_{R,2} would be at the bottom below the measurement value U_{R,1} measured at time t₁, a measurement value is preferably used that has been recorded before time t₁ (e.g., at a time to), in order to form, together with the measurement value U_{R,2} measured at time t₂, the differential quotient, which in turn is used to form the gradient triangle, which in turn is used to form the transformed measurement value.

The transformation factor a may be mildly temperature dependent.

The preceding notes are intended to serve as an explanation of the inventions reported as a whole in the application, which further develop the state of the art at least with the following feature combinations, also each on their own merits, wherein two, several or all of said feature combinations may also be combined, specifically:

A method that is characterized in that transformed values U*ᵢ are formed by the emissivity values U_{E,i} and/or reflectance values URL and are used instead of the emissivity values U_{E,i}, or reflectance values U_{R,i} in the calculation of the temperature values Tᵢ.

A method that is characterized in that the transformed values U*ᵢ are formed by a numerical time transformation of either the emissivity values U_{E,i} or the reflectance values U_{R,i}.

A method that is characterized in that at least two measurement values of the emissivity value U_{E,i} or of the reflectance value U_{R,i}, determined at different times, are each used in the calculation of the transformed values U*ᵢ.

A method that is characterized in that a transformation factor a used in the transformation Uᵢ(t)→U*ᵢ(t*ᵢ) is determined in preliminary tests and/or that the transformation factor a corresponds to the quotient of the angular frequencies ω_{E}, ω_{R}.

A method that is characterized in that during the deposition of the layer, a value U*ᵢ is determined for each of the measurement value pairs {U_{E,n}, U_{R,n}} according to the equation

$${U}_{i}^{*} = {U}_{i} - ( 1 - \frac{1}{a} ) \cdot {t}_{i} \cdot {U}_{i}^{′} ,$$

wherein tᵢ is the time t, optionally corrected by a phase offset, since the beginning of the deposition of the layer, Uᵢ is the measurement value of either the emissivity value U_{E,i} or the reflectance value U_{R,i} at time tᵢ, a is the transformation factor and U′ᵢ is the gradient of the curve through the measured emissivity values U_{E,i} or reflectance values U_{R,i} at time tᵢ, and the value U*ᵢ is used instead of the measurement value U_{E,i}, U_{R,i} to calculate the temperature.

A method that is characterized in that the gradient U′ᵢ is calculated by forming a differential quotient

$$\frac{{U}_{i} - {U}_{i - n}}{{t}_{i} - {t}_{i - n}}$$

of two measurement values measured temporally one after the other.

A method that is characterized in that the temperature value Tᵢ is calculated according to the following equation

$${T}_{i} = \frac{B}{ln ( {U}_{E , i} ) - ln ( A \cdot ( 1 - α \cdot {U}_{R , i} ) )} ,$$

wherein A, B and α are calibration parameters and one of the measurement values U_{E,i}, U_{R,i} is replaced by the time-transformed value U*ᵢ.

A method that is characterized in that the emissivity values U_{E,i} are time-transformed when the angular frequency ω_{E} of their curve progression is greater than the angular frequency ω_{R} of the curve progression of the reflectance values U_{R,i} and vice versa.

A method that is characterized in that the temperature value Tᵢ is used as an actual value T_{act} for a control loop of a temperature control device for controlling the temperature of the substrate, with which the substrate temperature is regulated with respect to a setpoint Tₛₑₜ.

A method that is characterized in that the transformation factor a is determined during a previously performed deposition of a layer on a substrate, wherein during the deposition measurement, value pairs {U_{E,n}, U_{R,n}} are recorded multiple times in succession, each containing an emissivity value U_{E,i} and a reflectance value U_{R,i}, and afterwards, periodic compensation curves are generated thereby.

A method that is characterized in that in order to determine the transformation factor a with first growth parameters, a layer is deposited on a substrate, measurement value pairs {U_{E,n}, U_{R,n}} are measured and stored during the deposition of the layer, and subsequently transformed values U*ᵢ are formed, by means of the transformation either from the stored emissivity values U_{E,i} or from the stored reflectance values U_{R,i} with an incrementally varied test value of the transformation factor a, which transformed values are used instead of the emissivity values U_{E,i} or the reflectance values U_{R,i} in a calculation of a temperature value T, wherein the test value is varied until the amplitude of a residual oscillation of a curve of the temperature value T calculated according to any one of the above methods and plotted over time is minimal.

A device that is characterized in that the computing device is configured to configured to form transformed values U*ᵢ from either the emissivity values U_{E,i} or the reflectance values U_{R,i} using a transformation according to any one of the above methods, and to use these instead of the emissivity values U_{E,i} or reflectance values U_{R,i} in the calculation of the temperature value Tᵢ.

A CVD reactor that is characterized by an apparatus for determining the temperature value Tᵢ of the substrate temperature according to the above device.

All disclosed features are essential to the invention (by themselves, but also in combination with one another). In the disclosure of the application the disclosure content of the associated/attached priority documents (copy of the previous application) is hereby also included in its entirety, also for the purpose of including features of these documents in claims of the present application. The subclaims, even without the features of a referenced claim, characterize with their features independent inventive developments of the prior art, in particular for making divisional applications on the basis of these claims. The invention specified in each claim can additionally have one or more of the features specified in the above description, in particular with reference numbers and/or specified in the list of reference numbers. The invention also relates to configurations in which individual features mentioned in the above description are not implemented, in particular if they are clearly superfluous for the respective intended use or can be replaced by other technically equivalent means.

### LIST OF REFERENCE SYMBOLS

1 Reactor housing
2 Gas inlet element
3 Gas supply line
4 Susceptor
5 Heating device
6 Substrate holder
6′ Gas cushion
7 Substrate
8 Process chamber
9 Drive shaft
10 Beam splitter
11 Reflectance measuring device
12 Emissivity measuring device
13 Measuring point
14 Rotary drive device
15 Computing device
α Calibration parameter
γ Correction value
γᵢ Correction value of a measurement interval
λ Wavelength
A Axis of rotation
A Calibration parameter
B Calibration parameter
U_{E} Emissivity value
U_{R} Reflectance value
U_{E,n} Emissivity value
U_{R,n} Reflectance value
T_{M} Measurement temperature
tᵢ Timepoint
i Index of a measurement
{U_{E,n}, U_{R,n}} Measurement value pair
T_{act} Actual value
ω_{E}, ω_{R} Angular reference
U_{R,i} Reflectance value
U_{E,i} Emissivity value
U*ᵢ, U*_{E,i} Transformed value
U′ᵢ, U*′ᵢ, U*′_{R,i} Temporal derivative

1. A method for coating a substrate (7) with a layer, the method comprising:
depositing the layer on the substrate (7);
during the deposition of the layer, determining measurement value pairs ({U_{E,n}, U_{R,n}}) multiple times in succession with at least one optical measuring device on the layer, each of which contains an emissivity value (U_{E,n}) that corresponds to a thermal radiation output measured at a first wavelength, and a reflectance value (U_{R,n}) measured at a second wavelength that differs from the first wavelength;
calculating temperature values (Tᵢ) of the substrate (7) from the measurement value pairs ({U_{E,n}, U_{R,n}}), wherein the emissivity values (U_{E,n}) lie on a first curve that oscillates with a first angular frequency (ω_{E}) over time (t), and the reflectance values (U_{R,n}) lie on a second curve that oscillates with second angular frequency (ω_{R}) over time (t), and a quotient of the first angular frequency (ω_{E}) and the second angular frequency (ω_{R}) differs from 1; and
through a numerical time transformation, in which at least two measurement values each of the emissivity value (U_{E,i}) or the reflectance value (U_{R,i}) calculated at different times are used, forming transformed values (U*ᵢ) from the emissivity values (U_{E,i}) and/or the reflectance values (U_{R,i}), wherein the temperature values (Tᵢ) are calculated using the transformed values (U*ᵢ) instead of the emissivity values (U_{E,i}) or the reflectance values (U_{R,i}),
wherein one of the emissivity values (U_{E,i}) or the reflectance values (U_{R,i}) is a current measurement value,
wherein one of (i) a first gradient value of the first curve of the emissivity values (U_{E,i}) is calculated from the emissivity values (U_{E,i}), or (ii) a second gradient value of the second curve of the reflectance values (U_{R,i}) is calculated from the reflectance values (U_{R,i}), and
wherein the transformed values (U*ᵢ) are calculated with the first gradient value or the second gradient value.

2. The method of claim 1, wherein at least one of:
a transformation factor (α) used for the time transformation (Uᵢ(t)→U*ᵢ(t*ᵢ)) is determined in preliminary tests, or
the transformation factor (α) corresponds to the quotient of the first angular frequency (ωF), and the second angular frequency (ω_{R}).

3. The method of claim 2, wherein during the deposition of the layer, the transformed value (U*ᵢ) is determined for each of the measurement value pairs ({U_{E,n}, U_{R,n}}) according to an equation
$${U}_{i}^{*} = {U}_{i} - ( 1 - \frac{1}{a} ) \cdot {t}_{i} \cdot {U}_{i}^{′} ,$$
wherein:
tᵢ is a time (t), corrected by a phase offset, since a beginning of the deposition of the layer,
Uᵢ is either the emissivity value (U_{E,i}) or the reflectance value (U_{R,i}) at the time tᵢ,
α is the transformation factor, and
U′ᵢ is the first gradient of the first curve of the emissivity values (U_{E,i}) or is the second gradient of the second curve of the reflectance values (U_{R,i}) at the time tᵢ, and
the transformed value U*ᵢ is used instead of Uᵢ to calculate the temperature.

4. The method of claim 3, wherein the first or second gradient (U′ᵢ) is calculated by forming a differential quotient
$$\frac{{U}_{i} - {U}_{i - n}}{{t}_{i} - {t}_{i - n}}$$
in which Uᵢ and Uᵢ₋ₙ represent either the emissivity values (U_{E,i}) or the reflectance values (U_{R,i}) measured at times tᵢ and tᵢ₋ₙ, respectively.

5. The method of claim 1, wherein the temperature values (Tᵢ) are calculated according to an equation
$${T}_{i} = \frac{B}{ln ( {U}_{E , i} ) - ln ( A \cdot ( 1 - α \cdot {U}_{R , i} ) )} ,$$
wherein A, B and α are calibration parameters and either the emissivity value (U_{E,i}) or the reflectance value (U_{R,i}) is replaced by the transformed value (U*ᵢ).

6. The method of claim 1, wherein the emissivity values (U_{E,i}) are time-transformed when the first angular frequency (ω_{E}) of the first curve of the emissivity values (U_{E,i}) is greater than the second angular frequency (ω_{R}) of the second curve of the reflectance values (U_{R,i}).

7. The method of claim 1, wherein each of the temperature values (Tᵢ) is used as an actual value (T_{act}) for a control loop of a temperature control device for controlling a temperature of the substrate (7), with which the substrate temperature is regulated with respect to a setpoint (Tₛₑₜ).

8. The method of claim 2, wherein the transformation factor (α) is determined during a previously performed deposition of a previous layer on a previous substrate, wherein during the previously performed deposition, previous measurement value pairs ({U_{E,n}, U_{R,n}}) are recorded multiple times in succession, and afterwards, periodic compensation curves are generated thereby.

9. The method of claim 2, wherein in order to determine the transformation factor (α) with first growth parameters, a previous layer is deposited on a previous substrate, measurement value pairs ({U_{E,n}, U_{R,n}}) are measured and stored during the deposition of the previous layer, and subsequently transformed values (U*ᵢ) are formed, by means of transformation either from the stored emissivity values (U_{E,i}) or from the stored reflectance values (U_{R,i}) with an incrementally varied test value of the transformation factor (α), which transformed values are used instead of the emissivity values (U_{E,i}) or the reflectance values (U_{R,i}) in a calculation of a temperature value (T), wherein the test value is varied until an amplitude of a residual oscillation of a curve of the temperature value (T) calculated according to claim 2 and plotted over time is minimal.

10. A device for performing the method of claim 1, the device comprising:
a first optical measuring device (12) for measuring the emissivity values (U_{E,i});
a second optical measuring device (11) for measuring the reflectance values (U_{R,i}); and
a computing device (15) for calculating the temperature values (Tᵢ), wherein the computing device (15) is configured to form the transformed values (U*ᵢ) from either the emissivity values (U_{E,i}) or the reflectance values (U_{R,i}), and to use these the transformed values (U) instead of the emissivity values (U_{E,i}) or the reflectance values (U_{R,i}) in the calculation of the temperature values (Tᵢ).

11. A chemical vapor deposition (CVD) CVD reactor with a temperature control device for controlling a temperature of a substrate (7), the CVD reactor comprising the device of claim 10.

12. (canceled)
